(19) United States
(12) Patent Application Publication
(10) Pub. No.: US 2012/0134098 A1
(43) Pub. Date: May 31, 2012

(54) COMPUTING DEVICE THERMAL MODULE

(76) Inventors: Steven S. Homer, Tomball, TX (US); Keith A. Sauer, Spring, TX (US); David W. Cawthon, Houston, TX (US); Jeffrey A. Lev, Tomball, TX (US); Mark S. Tracy, Tomball, TX (US); Earl W. Moore, Cypress, TX (US)

(21) Appl. No.: 13/387,173

(22) PCT Filed: Sep. 22, 2009
(86) PCT No.: PCT/US09/57932

§ 371 Date: Jan. 26, 2012

(51) Int. Cl. G06F 1/20; H05K 13/00; G06F 1/16

(52) U.S. Cl. 361/679.33; 361/679.46; 361/679.47; 29/592.1

(57) ABSTRACT

A computing device and method have a thermal module (60, 161, 460) in a bay (54, 354) for a component so as to occupy space otherwise occupied by the component.

### BACKGROUND

In some computing devices, thermal modules are utilized to cool central processing units and other heat generating components. A size of the central processing unit or other heat generating components may be limited based upon a cooling capacity of the thermal module.

### BRIEF DESCRIPTION OF THE DRAWINGS

FIG. 1 is a schematic view of a computing device according to an example embodiment.

FIG. 2 is a schematic view of another embodiment of the computing device of FIG. 1 according to an example embodiment.

FIG. 3 is a schematic view of another embodiment of the computing device of FIG. 1 according to an example embodiment.

FIG. 4 is a schematic view of a computing device with a layout having a computing device component in a computing device hay.

FIG. 5 is a schematic view of the computing device of FIG. 4 with an alternative layout having an enlarged thermal module extending into the computing device bay according to an example embodiment.

### DETAILED DESCRIPTION OF THE EXAMPLE EMBODIMENTS

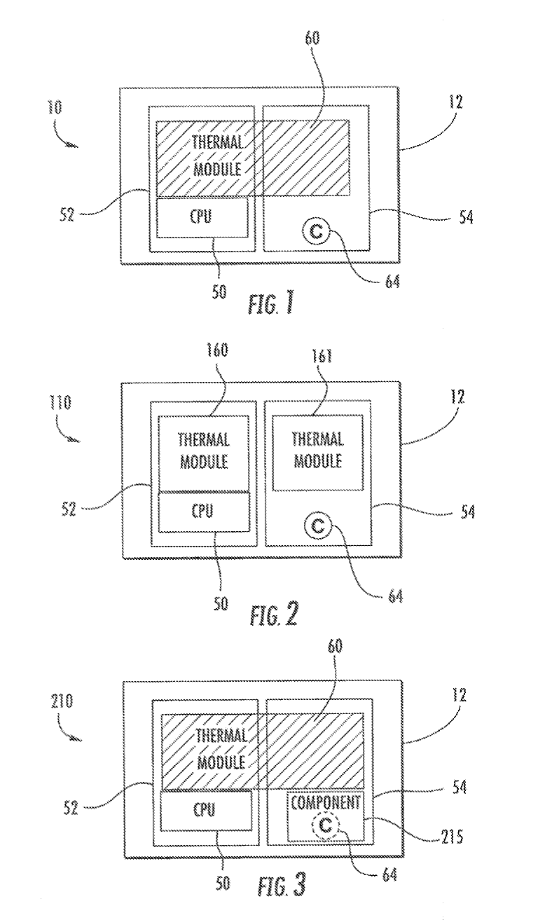

FIG. 1 schematically illustrates computing device 10 according to an example embodiment. Computing device 10 includes one or more processing units that perform one more computing operations during which heat is generated. As will be described hereafter, computing device 10 has an architecture or layout facilitating use of a larger thermal module or the use of additional thermal modules for enhanced cooling or dissipation of the heat. As a result, computing device 10 may include a larger, more powerful processing unit or other heat generating components without increasing a size of computing device 10.

Computing device 10 includes housing 12, a heat generating component 50, thermal module bay 52, computing device component bay 54 and thermal module 60. Housing 12 comprises one or more structures configured to surround, enclose and support remaining components of computing device 12. Housing 12 forms an outermost structure or shell containing the remaining structures of device 12. In one embodiment in which computing device comprises a laptop or notebook computer, housing 12 may support a keyboard and/or key pad opposite to a hinged display or monitor.

Heat generating component 50 comprises one or more components contained within housing 12 and configured to generate heat during their operation. In the example illustrated, component 50 comprises a central processing unit (CPU). The CPU controls the remaining components of device 10 and performs computing operations or processes. During its operation, the CPU generates substantial quantities of heat which must be dissipated to avoid damage to CPU or to other components of device 10. Although not shown, device 10 may include other controllers and processors or other heat generating components for which the heat must also be dissipated.

Thermal module bay 52 comprises one or more structures within housing 12 that form or define a cavity, chamber or space sized, located and shaped to receive and hold a thermal module such as a fan, a heat sink, heat dissipating structures such as fins, for heat transfer elements such as a heat pipe. For purposes of this disclosure, the term “bay” refers to a cavity or space designated and configured for receiving and mounting a computer component or thermal module. For purposes of this disclosure, a “thermal module” refers to a computer component or a grouping of interconnected or adjacent computer components that cooperate to transfer or dissipate heat. Thermal module bay 52 is located such that the thermal module it contains may effectively dissipate heat from heat generating component 50. In the example illustrated, thermal module bay is located adjacent or in an overlapping relationship to the heat generating component 50 which comprises a central processing unit. Although illustrated as rectangular, bay 52 may have other shapes and may have other locations with respect to heat generating component 50.

Computing device component bay 54 comprises one or more structures within housing 12 that form or define a cavity, chamber or space sized, located and shaped to receive and hold a computing device component other than a thermal module. Examples of components for which bay 54 is configured to hold include either optional components or mandatory components. Optional components are components that computing device 10 may operate without. Examples of optional components include, but are not limited to, optical disc drives (i.e., compact disc drives, digital versatile disc drives, blue ray drives and other drives using optics to read and/or write data to/from a disc) and hard disk drives (where another persistent storage device is provided such as a flash drive). Mandatory components are components that device 10 must have to operate in an expected manner. For example, a laptop or notebook computer is expected to be able to operate without necessarily being plugged in to an electrical outlet. Examples of such mandatory components include, but are not limited to, a battery, a central processing unit and the like.

As further shown by FIG. 1, computing device component bay 54 additionally includes a connector 64 configured for electrical connection to a computing device component located within component bay 54. In particular, connector 64 is configured for electrical connection to a computing device component other than a thermal module. Connector 64 facilitate transmission a electrical power or data signal between the computing device component located within component bay 54 and other components of computing device and such as the central processing unit. In one embodiment, connector 64 comprises a male or female plug or plug-in port setting one or more socket or connector pins. In other embodiments, connector 64 may have other configurations.

Thermal module 60 comprises a unit of one or more components which cooperate with one another to dissipate heat or extract heat from one or more components or areas of computing device 10. Examples of components which may comprise part of thermal module 50 include, but are not limited to, a heat sink, a thermally conductive plate formed from metals having a high thermal conductivity such as aluminum or copper, a heat pipe, a fan or blower, phase change thermosyphons and thermoelectric cooling units. In one embodiment in which generating component 50 comprises a central processing unit, thermal module 60 comprises a thermally conductive plate having a high degree of thermal conductivity, such as in an aluminum plate with a large surface area, adjacent and overlapping the central processing unit, a fan adjacent the thermally conductive plate and a heat pipe directing airflow from the fan across the CPU and across additional portions of the thermally conductive plate. In other embodiments, thermal module 60 may have other configurations.

As schematically shown by FIG. 1, thermal module 60 extends or projects beyond thermal module bay 52 into computing device component bay 54. Instead of computing device component bay 54 receiving and connecting to a computing device component, whether an optional component or a mandatory component, the space within computing device component bay 54 designated for a computing device component is occupied by thermal module 60. Connector 64 is unused. The additional space provided by computing device component bay 54 facilitates the use of a larger thermal module 60. As a result, computing device 10 may be provided with additional heat dissipation capacity, allowing higher heat generating components, such as a larger more powerful central processing unit.

According to one embodiment, thermal module 60 has a larger expanse of a thermally conductive plate and a longer heat pipe which project or extend from within thermal module bay 52 into computing device component bay 54. According to one embodiment, thermal module 60 occupies at least 25% of the space available within computing device component bay 54 that would otherwise be occupied by computing device component. According to one embodiment, thermal module 60 occupies at least 50% and nominally at least 75% of computing device component bay 54. In other embodiments, thermal module 60 may have other components projecting into computing device component 54 and may occupy other extents of computing device component bay 54.

FIG. 2 schematically illustrate computing device 110, another embodiment of computing device 10. Computing device 110 is similar to computing device 10 except that computing device 110 includes thermal modules 160 and 161 in place of thermal module 60. Those remaining elements of computing device 110 that correspond to elements of computing device 10 are numbered similarly.

Thermal modules 160 and 161 each comprise a unit of one or more components which cooperate with one another to dissipate heat or extract heat from one or more components or areas of computing device 10. Examples of components which may comprise part of thermal module 160 or thermal module 161 include, but are not limited to, a heat sink, a thermally conductive plate, a heat pipe and a fan or blower. In one embodiment in which heat generating component 50 comprises a central processing unit, thermal module 160 comprises a thermally conductive plate having a high degree of thermal conductivity, such as in an aluminum plate with a large surface area, adjacent and overlapping the central processing unit, a fan adjacent the thermally conductive plate and a heat pipe directing airflow from the fan across the CPU and across additional portions of the thermally conductive plate. In other embodiments, thermal module 160 may have other configurations. Unlike thermal module 60, thermal module 161 is entirely contained within thermal module bay 52.

Thermal module 161 is separate and distinct from thermal module 160. Thermal module 161 does not extend or project into thermal module bay 52. Instead, thermal module 161 is located within computing device component bay 54. Although thermal module 161 is illustrated as being entirely contained within computing device component bay 54, in other embodiments, thermal module 161 may alternatively extend or project into other adjacent bays of housing 12.

Instead of computing device component bay 54 receiving and connecting to a computing device component, whether an optional component or a mandatory component, the space within computing device component bay 54 designated for a computing device component is occupied by thermal module 161. Connector 64 is unused. The additional space provided by computing device component bay 54 facilitates the use of an additional or extra thermal module 161. As a result, computing device 110 may be provided with additional heat dissipation capacity, allowing higher heat generating components, such as a larger more powerful central processing unit, or additional heat generating components.

FIG. 3 the schematically illustrates computing device criminal 210, another embodiment of computing device 10. Computing device 210 is similar to computing device 10 except that computing device 210 additionally includes computing device component 215. Those remaining elements of computing device 210 which correspond to elements of computing device 10 are numbered similarly.

Computing device component 215 comprises either an optional component or a mandatory component other than a thermal module which is connected to computing device 210 via connector 64. Computing device component 215 is positioned within computing device component bay 54. Computing device component 215 is utilized in computing device 210 in place of a synonymous, but larger computing device component that would otherwise be located within computing device component bay 54.

For example, in one embodiment, computing device component bay 54 may comprise a bay configured for connection to and positioning of a first hard drive of a first size or dimension. In such a case, computing device 210 utilizes a computing device component 215 comprising a second hard drive of a second smaller size or a second smaller dimension. The second hard drive is sufficiently smaller than the first hard drive so as to make available space within computing device component bay 54 sufficient to receive portions of the larger thermal module 60 or so as to receive a second additional thermal module. In another embodiment, computing device component bay 54 may comprise a bay configured for connection to and positioning of a first battery of a first size or dimension. In such a case, computing device 210 utilizes a computing device component 215 comprising a second battery of a second smaller size or a second smaller dimension. The second battery is sufficiently smaller than the first battery so as to make available space within computing device component bay 54 sufficient to receive portions of the larger thermal module 60 or so as to receive a second additional thermal module. In yet another embodiment, computing device component bay 54 may comprise a bay configured for connection to and positioning of an optical drive of a first size or dimension. In such a case, computing device 210 utilizes a computing device component 215 comprising a second optical drive of a second smaller size or a second smaller dimension. The second optical drive is sufficiently smaller than the first optical drive so as to make available space within computing device component bay 54 sufficient to receive portions of the larger thermal module 60 or so as to receive a second additional thermal module. According to one embodiments, the additional space within computing device component bay 54 made available by the alternative smaller computing device component 215 is at least 100 cubic millimeters for receiving the larger thermal module 60 or for receiving an additional thermal module such as an additional thermal module 161 above and be on thermal module 160 (shown in FIG. 2).

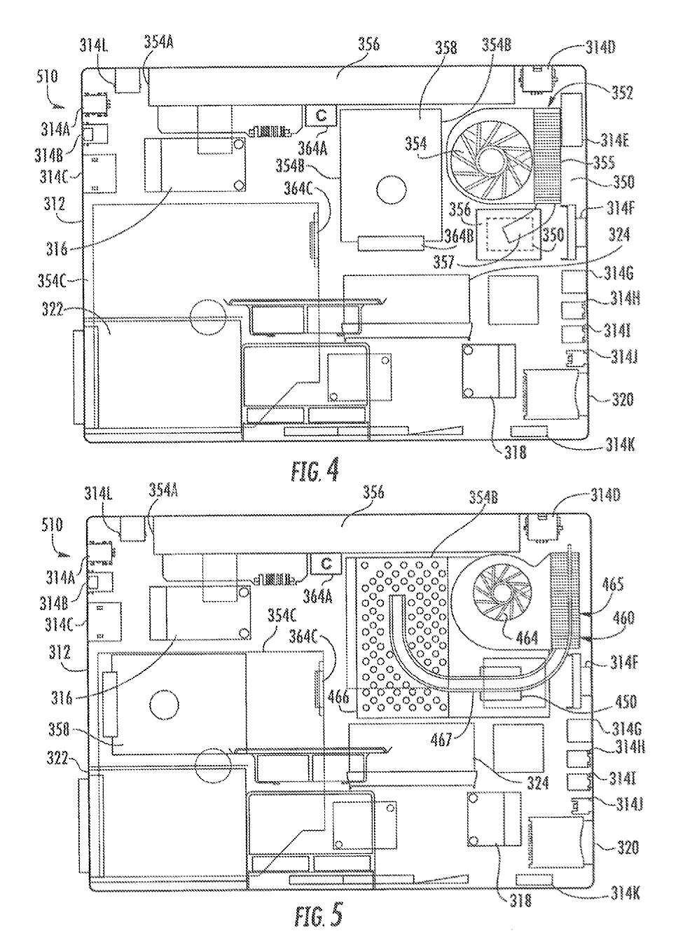

FIG. 4 schematically illustrates a computing device 310 having a layout with computing device component in a computing device bay. By way of contrast, FIG. 5 schematically illustrates a computing device 510 having an alternative layout wherein an enlarged, more expansive thermal module extends into the computing device bay in space that would otherwise be occupied by a computing device component. As a result, the layout of the computing device 510 facilitates use of a larger thermal module with greater heat dissipation capacity. This greater heat dissipation capacity permits computing device 510 to utilize a more powerful central processing unit that generates a greater amount of heat.

Computing devices 310 and 510 each comprise housing 312, communication ports 314A-314L (collectively referred to as communication ports 314), communication cards 316, memory card reader 320, smartcard reader 322, memory card 324, thermal module bay 350, computing device component bays 354A-354C (collectively referred to as computing device component bays 354), battery 356 and hard disk drive 358. Communication ports 314 facilitate communication between computing devices 310, 510 and external devices are connection of computing devices 310, 510 to an external power source. In the example illustrated, communication port 314A facilitates connection of computing devices 310, 510 to an external DC power source. Communication port 314B is a RJ11 connector. Communication port 314C is a display port facilitating connection to an external display. Communication port 314D is a RJ45 connector. Communication port 314E is a dock connector for the dating connection of computing device 3102 a personal computing device stock. Communication port 314E is a VGA port. Communication port 314G and 314L are universal serial bus ports. Communication port 3141-1 is a microphone port while communication port 3141 is a headphone port. Communication port 314J is an IEE 394 port. Communication port 314K is a Bluetooth port. In other embodiments, computing devices 310, 510 may have a greater or fewer number of such communication ports.

Communication card 316 is a circuit card facilitating wireless connection of computing device 310, 510 to a wireless phone network. In one embodiment, communication part 316 comprises a wide area network (WAN) Mini card. Communication card 318 comprises circuit card facilitating connection to a wireless network generally supported by a router. In one embodiment, communication card 31 comprises a wLan-WIMax Mini card. In other embodiments, computing device to row 310, 510 may comprise other types of communication cards. In some embodiments, one or both of such cards may be omitted.

Card reader 320 comprises a device configured to receive or otherwise make connection to an external or portable circuit card, such as a memory card. For example, in one embodiment, card reader 320 is configured to read flash memory cards. In other embodiments, card reader 320 may be omitted.

Smartcard reader 322 comprises a device configured to receive or otherwise make connection to an external or portable smartcard. The smartcard comprises a portable circuit card or board containing or including an authorization key or other security measures authorizing access to data our systems on computing device 310, 510. In other embodiments, smartcard reader 322 may be omitted.

Thermal module bay 352 comprises one or more structures within housing 312 that form or define a cavity, chamber or space sized, located and shaped to receive and hold a thermal module such as a fan, a heat sink, heat dissipating structures such as fins, for heat transfer elements such as a heat pipe. Thermal module bay 352 is located such that the thermal module it contains may effectively dissipate heat from one or more heat generating components. In the example illustrated, thermal module bay is located adjacent or in an overlapping relationship to a heat generating component which comprises a central processing unit. Although illustrated as rectangular, bay 352 may have other shapes and may have other locations with respect to heat generating components.

Computing device component bays 354 each comprises one or more structures within housing 312 that form or define a cavity, chamber or space sized, located and shaped to receive and hold a computing device component other than a thermal module. Examples of components for which bay 354 is configured to hold include either optional components or mandatory components. Optional components are components that computing device 310, 510 may operate without. Examples of optional components include, but are not limited to, optical disc drives (i.e., compact disc drives, digital versatile disc drives, blue ray drives and other drives using optics to read and/or write data to/from a disc) and hard disk drives (where another persistent storage device is provided such as a flash drive). Mandatory components are components that device 10 must have to operate in an expected manner. For example, a laptop or notebook computer is expected to be able to operate without necessarily being plugged in to an electrical outlet. Examples of such mandatory components include, but are not limited to, a battery, a central processing unit and the like.

In the example illustrated, bay 354A comprises a bay configured to removably receive battery 356 for computing device 310, 510. As such, bay 354A includes one or more connectors 364A (schematically shown) for electrical connection to the battery 356. In one embodiment, connector 64 comprises a male or female plug or plug-in port setting one or more socket or connector pins. In other embodiments, connector 364A may have other configurations. In the example illustrated, bay 354A is configured to receive a 2510p notebook or laptop computer battery. In other embodiments, bay 354 may have other configurations for receiving other batteries or may be omitted.

Computing device component bay 354B comprises a bay configured to removably receive hard disk drive 358. Computing device component bay 3548 extends adjacent to a long or beside thermal module bay 350. In the example illustrated, hard disk drive 358 comprises a 1.8 inch hard disc drive. In other embodiments, hard disk drive 358 may have other configurations and may comprise other types of hard drives. Likewise, computing device component bay 354B may have other configurations or locations. Computing device component bay 354B includes one or more interfaces or connectors 364B (schematically shown) facilitating power and data transmission to and from hard disk drive 358. In one embodiment, connector 364B comprises a male or female plug or plug-in port setting one or more socket or connector pins. In other embodiments, connector 64 may have other configurations.

Computing device component bay 354C comprises a bay configured to removably receive an optical disk drive. Examples of optical disk drives include, but are not limited to, compact disc drives, digital versatile disc drives, blue ray drives and other drives using optics to read and/or write data to/from a disc.

Computing device component being 354C includes an interface or connector 364C compared to facilitate power and data transmission between the optical disk drive placed in bay 354C and remaining components of computing device 310, 510. In the example illustrated, connector 364C is also configured to provide power and data transmission between hard disk drive 358 and computing device 310, 510 when hard disk drive 358 is connected to connector 364C. In other embodiments, bay 354C may include a separate connector designated for connection to hard disk drive 358. In one embodiment, connector 364C comprises a male or female plug or plug-in port setting one or more socket or connector pins. In other embodiments, connector 64 may have other configurations.

Although computing devices 310 and 510 each have the aforementioned same elements, computing devices 310, 510 have distinct or different layouts facilitating use of distinct heat generating components and distinct thermal modules. As shown by FIG. 4, computing device 310 includes a heat generating component comprising a central processing unit 350 and a thermal module 352. Central processing unit (CPU) 350 controls the remaining components of device 310 and performs computing operations or processes. During its operation, the CPU 350 generates substantial quantities of heat which must be dissipated to avoid damage to CPU 350 or to other components of device 310. Although not shown, device 310 may include other controllers and processors or other heat generating components for which the heat must also be dissipated. In the embodiment illustrated, CPU comprises a low-power CPU such as a 25 Watt CPU. In other embodiments, CPU 350 may comprise other types of central processing units or have other configurations.

Thermal module 352 comprises a unit of one or more components which cooperate with one another to dissipate heat or extract heat from one or more components or areas of computing device 310. Examples of components which may comprise part of thermal module 350 include, but are not limited to, a heat sink, a thermally conductive plate, a heat pipe and a fan or blower. In the example illustrated in which the generating component cooled by thermal module 352 comprises a central processing unit, thermal module 350 comprises a fan 354 adjacent fin 355, a thermally conductive plate 356 and a heat pipe 357 directing airflow from the fan 354 across the CPU 350 and across the thermally conductive plate 356 which overlies CPU 350. In the example illustrated, thermal module 352 comprises a two-spindle 27 W thermal module having a 65×55×10 mm fan 354. In other embodiments, thermal module or 352 may have other configurations.

As shown by FIG. 5, computing device 510 has a different layout or architecture as compared to computing device 310. In particular, instead of being located within bay 354B, hard disk drive 358 is alternatively position within bay 354C in place of any optical disk drive. Hard disk drive 358 is connected to be a connector 364C or another connector provided in bay 354C for hard disk drive 358. The vacated space or area within bay 354B, extending alongside her adjacent to thermal module bay 350, provides extra room facilitating use of a larger thermal module and a more powerful central processing unit in computing device 510 as compared to device 310.

In contrast to computing device 310, computing device 510 includes central processing unit 450 and thermal module 460. Central processing unit (CPU) 450 controls the remaining components of device 510 and performs computing operations or processes. During its operation, the CPU 450 generates substantial quantities of heat which must be dissipated to avoid damage to CPU 450 or to other components of device 510. Although not shown, device 510 may include other controllers and processors or other heat generating components for which the heat must also be dissipated. In the example illustrated, CPU comprises a CPU having a higher power or higher heat generating CPU as compared to CPU 350. In the example illustrated, CPU 450 comprises a 35 Watt CPU. In other embodiments, CPU 450 may comprise other types of central processing units or have other configurations.

Thermal module 460 comprises a unit of one or more components which cooperate with one another to dissipate heat or extract heat from one or more components or areas of computing device 510. Examples of components which may comprise part of thermal module 460 include, but are not limited to, a heat sink, a thermally conductive plate, formed from metals having a high thermal conductivity such as aluminum or copper, a heat pipe, a fan or blower, phase change thermosyphons and thermoelectric cooling units. In the example illustrated in which the generating component cooled by thermal module 452 comprises a central processing unit, thermal module 460 comprises a fan 464 adjacent fin 465, a thermally conductive plate 466 and a heat pipe 467 directing airflow from the fan 464 across the CPU 450 and across the thermally conductive plate 466 which overlies CPU 450. In the example illustrated, thermal module 352 comprises a two-spindle 27 W thermal module having a 65×55×10 mm fan 354. In other embodiments, thermal module or 352 may have other configurations.

As shown by FIG. 5, conductive plate 466 (formed from aluminum or copper) and heat pipe 467 are larger than plate 356 and heat pipe 357, respectively, and project over and into the vacated computing device component bay 354B. The additional cooling capacity provided by the larger conductive plate 466 and the larger heat pipe 467 more effectively dissipate the additional amount of heat generated by the more powerful CPU 450. As a result, computing performance is enhanced without increasing the size of computing device 510 or its housing 312.

Although the present disclosure has been described with reference to example embodiments, workers skilled in the art will recognize that changes may be made in form and detail without departing from scope of the claimed subject matter. For example, although different example embodiments may have been described as including one or more features providing one or more benefits, it is contemplated that the described features may be interchanged with one another or alternatively be combined with one another in the described example embodiments or in other alternative embodiments. Unless specifically otherwise noted, the claims reciting a single particular element also encompass a plurality of such particular elements.

What is claimed is:

1. A computing device comprising:
a housing;
a central processing unit within the housing;
a bay within the housing and having a connector configured for electrical connection to a first computing device component other than a thermal module; and
a first thermal module within the bay occupying space otherwise occupied by the first computing device component.

2. The computing device of claim 1, wherein the first computing device component is an optional computing device component not required for operation of the computing device.

3. The computing device of claim 2, wherein the optional computing device component is selected from a group of components consisting of an optical drive and a hard drive.

4. The computing device of claim 1, wherein the first computing device component is mandatory for the operation of the computing device and wherein the computing device includes a second computing device component in place of the first computing device component in the bay, wherein the second computing device component occupies less space than the first computing device component.

5. The computing device of claim 4, wherein the first computing device comprises a first battery and wherein the second computing device component comprises a second battery smaller than the first battery.

6. The computing device of claim 1 further comprising a second thermal module within the housing.

7. The computing device of claim 1, wherein the first thermal module extends from outside the bay into the bay.

8. The computing device of claim 1, wherein at least one of a conductive plate and a heat pipe of the first thermal module extend into the bay.

9. The computing device of claim 1, wherein the computing device comprises a notebook computer.

10. The computing device of claim 1, wherein the bay is configured to receive a hard disk drive component and wherein the device further comprises a second bay having a connector configured for electrical connection to an optical disk drive, wherein the hard disk drive component is connected in the second bay and wherein the thermal module projects into the bay occupying space otherwise occupied by the hard disk drive.

11. A method comprising:
removing an optional component or replacing an optional component or mandatory component with the smaller corresponding component to create an unused cavity in a bay of a computing device; and
positioning a thermal module into the unused cavity.

12. The method of claim 11 comprising extending a thermal module from an adjacent bay into the unused cavity.

13. The method of claim 12, wherein positioning the thermal module comprises enlarging a thermally conductive plate or extending a heat pipe of the thermal module into the unused cavity.

14. The method of claim 11 further comprising enlarging power of a processor (50, 450) cooled by the thermal module (60, 161, 460).

15. The method of claim 11, wherein the computing device comprises a notebook computer (510).
